(19) United States
(12) Patent Application Publication
(10) Pub. No.: US 2025/0204656 A1
(43) Pub. Date: Jun. 26, 2025

(54) TRIM COMPONENT COMPRISING A SUBSTRATE HAVING LOCAL VARIATIONS IN REFRACTIVE INDEX, AND METHOD OF PRODUCING SUCH A TRIM COMPONENT

(71) Applicant: The Swatch Group Research and Development Ltd, Marin (CH)

(72) Inventors: Camille HALLER, Yverdon-les-Bains (CH); Mina MORADI, Olten (CH); Vladislav SPASSOV, Praz (CH); Marion GSTALTER, Villers-Le-Lac (FR); Ahmad ODEH, Renens (CH); Simon SPRINGER, Berne (CH)

(73) Assignee: The Swatch Group Research and Development Ltd, Marin (CH)

(21) Appl. No.: 18/890,976

(22) Filed: Sep. 20, 2024

(30) Foreign Application Priority Data
Dec. 20, 2023 (EP) 23218769.0

(51) Int. Cl. A44C 27/00

(52) U.S. Cl. CPC A44C 27/007

(57) ABSTRACT

A trim component (10) including a substrate (11) having a trim face (110) and including a decorative area (12, 13), a first portion (111) of the trim face (110) being defined by the decorative area (12, 13), the remainder of the trim face (110) defining a second portion (112) of the trim face (110), the first portion (111) of the trim face (110) having a refractive index different from that of the second portion (112) of the trim face (110), the whole of the the trim face (110) being covered with a transparent and/or translucent coating (14) with a thickness of between 5 nm and 1 μm so as to give the trim face (110) interference colours, the colour of the first and second portions (111, 112) of the trim face (110) being different.

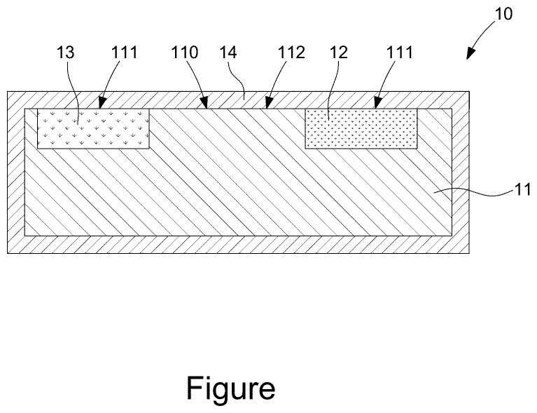

### CROSS REFERENCE TO RELATED APPLICATIONS

This application claims priority to European Patent Application No. 23218769.0 field Dec. 20, 2023, the entire contents of which are incorporated herein by reference.

### TECHNICAL SCOPE OF THE INVENTION

The invention relates to the field of horology, jewellery or jewellery-making and concerns in particular a trim component comprising a substrate with local variations in its refractive index.

### TECHNOLOGICAL BACKGROUND

Thin films are commonly used in the field of horology to modify the optical properties, and therefore the aesthetic appearance, of the visible surface of external components.

Several methods can be used to deposit thin films, including physical vapour deposition (PVD), chemical vapour deposition (CVD), atomic layer deposition (ALD) and galvanic growth.

Thin films can be made of pure metal, metal alloys or ceramic materials.

However, these thin films offer a relatively limited range of intrinsic colours depending on their composition and thickness.

A wider range of colours and more saturated colours can be obtained by way of interference colours obtained by stacking different thin layers, typically made of translucent material, deposited on a reflective layer.

All the aforementioned thin layers are monochrome and a multicoloured decoration requires as many deposition stages as there are colours required, said deposition stages being followed by intermediate structuring stages, typically carried out by photolithography and chemical etching, a process known as “lift-off”, “shadow mask”, or ablation by laser or reactive ion etching.

These structuring stages are often tedious and costly to ensure that they comply with tolerance requirements.

There is therefore a need to provide a component including several bright, saturated colours over a wide colour palette.

### SUMMARY OF THE INVENTION

The present invention relates to a trim component comprising a substrate having a trim face and including a decorative area, a first portion of the trim face being defined by the decorative area, the remainder of the trim face defining a second portion of the trim face. The first portion of the trim face has a refractive index different from that of the second portion, the whole of the said trim face being covered with a transparent or translucent coating whose thickness is between 5 nm and 1 μm so as to give the trim face interference colours, the colour of the first and second portions of the trim face being different.

In this text, we refer to a colour generated by an optical interference phenomenon as an “interference colour”.

In this way, a wide range of intense, saturated colours can be generated on a trim component in a relatively simple way.

In particular embodiments, the invention may further include one or more of the following features, taken either alone or in any technically possible combination.

In particular embodiments, the decorative area of the substrate has a crystalline phase and the rest of the substrate has an amorphous phase, or vice versa.

In particular embodiments, the decorative area of the substrate and the rest of the substrate have different crystalline structures.

In particular embodiments, the decorative area of the substrate and the rest of the substrate have different crystal plane orientations.

In particular embodiments, the decorative area of the substrate has a different chemical composition to that of the rest of the trim face.

In particular embodiments, the substrate is made of metal, glass, sapphire, ceramic material, polymer or a metal matrix composite material.

In particular embodiments, the coating is formed by a layer of oxide, nitride, fluoride, carbide, boride or a combination of at least two of these elements.

In particular embodiments, the coating is formed by a stack of layers made of oxide, nitride, fluoride, carbide and/or a combination of at least two of these elements.

In particular embodiments, the coating is formed by a stack of layers consisting of two layers of TiO2 with a layer of Al2O3 interposed in between.

In particular embodiments, the coating is configured so as to impart to the trim component a colour characterized in the space L*a*b* by L* of between 28 and 60, a* of between −9 and −0.6 and b* of between 21 and 31.

Another aspect of the invention relates to a method of producing a decoration on a trim component, for example in accordance with that previously described, comprising a step of local surface treatment of the trim face of a substrate, in which a decorative area is generated in the substrate on part of the trim face so that it has a different refractive index from the rest of the trim face, the method comprising a step of depositing a coating on the whole of the trim face produced so that the trim face has interference colours.

In particular modes of implementation, the local surface treatment step is carried out by laser so as to generate local annealing of the trim face in order to produce the decorative area by phase change, crystalline structure change, surface diffusion, oxidation, reduction or nitriding.

In particular modes of implementation, the local surface treatment step is carried out by electron beam evaporation, ion bombardment or electron beam lithography so as to generate a local change in the chemical composition of the trim face in order to produce the decorative area.

### BRIEF DESCRIPTION OF THE FIGURES

Other features and advantages of the invention will become apparent from the following detailed description, which is given by way of example and is by no means limiting, with reference to the FIGURE, which schematically shows a cross-sectional view of a trim component according to one embodiment of the present invention.

### DETAILED DESCRIPTION OF THE INVENTION

The present invention relates to a trim component 10 comprising a substrate 11 having, on a first portion 111 of a trim face 110, at least one decorative area 12, 13. The substrate 11 can be made of metal, glass, sapphire, ceramic material, polymer or metal matrix composite material, or more generally of any material whose atomic arrangement can be modified. By way of example, the substrate 11 may be made of CrNi, CrC or an alloy of gold and nickel.

The FIGURE shows a trim component 10 with two different decorative areas 12 and 13. However, to make the text easier to read, a single decorative area is described below.

The decorative area 12 or 13 is produced by local surface treatment of the display face 110, so that the decorative area 12 or 13 has a refractive index different from that of the rest of the display face 110, i.e. of a second, untreated portion 112 of the display face 110. In the present text, the term surface treatment may also refer to volume treatment, insofar as the latter gives rise to a surface treatment. In particular, as shown in the FIGURE, the surface treatment generates the decorative area 12 or 13 extending into the volume of the substrate 11. By way of example, the decorative area 12 or 13 resulting from the surface treatment may extend into the volume of the substrate to a depth equal to 100 μm.

The whole of the trim surface 110 is covered with a transparent and/or translucent coating 14, the thickness of which is between 5 nm and 1 μm, so as to give the trim surface 110 interference colours. As the refractive indices of the decorative area 12 or 13, i.e. of the first portion 111 of the trim surface 110, and that of the second portion 112 of the trim surface 110 are different, their colours are different and the decorative area 12 or 13 forms a coloured decorative pattern on the trim surface 110.

The invention includes several variants for producing this coloured decorative pattern.

In a first embodiment, the substrate 11 has an amorphous phase and the local surface treatment of the trim surface 110 enables the amorphous phase to be transformed locally into a crystalline phase. In this way, the decorative area 12 or 13 has a crystalline phase and the rest of the substrate 11 has an amorphous phase.

The local surface treatment is preferably carried out by laser so as to generate local annealing of the trim surface. This annealing may have the effect of locally reducing or oxidising the surface of the substrate 11.

Conversely, the substrate 11 may have a crystalline phase and the local surface treatment of the trim surface 110 enables the crystalline phase to be transformed locally into an amorphous phase. In this way, the decorative area 12 or 13 has an amorphous phase and the rest of the substrate 11 has a crystalline phase. In this example, substrate 11 can be made of sapphire or diamond.

In a second embodiment, the decorative area 12 or 13 is made so that it has a different crystalline structure from the rest of the substrate 11.

In a third embodiment, the decorative area 12 or 13 is made so that it has a crystal plane oriented differently to a crystal plane of the rest of the substrate 11.

In these embodiments, these different configurations of the decorative area 12 or 13 are obtained according to the material of the substrate 11 and the laser parameters. The modification of these parameters according to the desired result is within the reach of the person skilled in the art.

In a fourth embodiment of the invention, the decorative area 12 or 13 is produced so as to have a different chemical composition from that of the second portion 112 of the trim face 110. By way of example, the substrate 11 can be treated locally by electron beam evaporation or lithography so as to generate a local change in the chemical composition of the trim face in order to produce the decorative area 12 or 13.

In particular, atoms may migrate from the substrate 11 to the trim surface 110, for example if the substrate 11 is made of a metal alloy or of doped crystalline silicon. Furthermore, atoms may be lost, for example by evaporation, or atoms may be gained on the trim surface 110, for example by oxidation in ambient air or by nitriding in a controlled atmosphere.

The loss or gain of atoms can be achieved by sputtering or any other suitable method.

To obtain at least two different decorative areas 12 and 13 on the trim surface 110, several local surface treatment solutions from among those mentioned above are used.

The coating 14 can be formed by a layer of oxide, nitride, fluoride, carbide, boride or a combination of at least two of these elements, or it can be formed by a stack of these layers. It is preferably deposited by ALD or PVD methods. Alternatively, it may be deposited by any suitable thin film deposition method.

In particular, in one embodiment, the coating 14 is formed by a stack of layers consisting of two TiO2 layers with an Al2O3 layer interposed in between. More specifically, a first layer of TiO2 is deposited on the trim surface 110 of the substrate 11 and has a thickness of between 5 and 15 nm, or even between 6.5 and 9 nm. A layer of Al2O3 is deposited on the first TiO2 layer and has a thickness of between 60 and 70 nm, for example between 62 and 68 nm. Finally, a second TiO2 layer is deposited on the Al2O3 layer and has a thickness of between 25 and 35 nm, for example between 28 and 31 nm.

These features of the coating 14, in combination with a substrate 11 made of glass, make it possible to give the trim component 10 a colour characterised in the space L*a*b* by L* of between 28 and 60, a* of between −9 and −0.6 and b* of between 21 and 31. In particular, the trim component 10 has a green colour; the first portion 111, i.e. the decorative area(s) 12 and 13, in other words the first portion 111 and the second portion 112 of the trim face 110 having different shades of green respectively.

In general terms, the coating 14 can be made up of a stack of layers, each dimensioned so as to have a thickness of between 1 and 100 nm and so that the coating has a thickness of between 5 and 200 nm.

More generally, it should be noted that the implementations and embodiments considered above have been described by way of non-limiting examples, and that other variants are therefore conceivable.

It should be noted that, in the present text, the substrate 11 may consist of a substrate body and a coating deposited on said substrate body. In this case, the trim face 110 of the substrate 11 is formed by the visible face of the coating and the decorative area(s) 12 and 13 are formed in said coating.

1. A trim component (10) comprising a substrate (11) having a trim face (110) and including a decorative area (12, 13), a first portion (111) of the trim face (110) being defined by the decorative area (12, 13), the remainder of the trim face (110) defining a second portion (112) of the trim face (110), the first portion (111) of the trim face (110) having a refractive index different from that of the second portion (112) of the trim face (110), the whole of the said trim face (110) being covered with a transparent and/or translucent coating (14) with a thickness of between 5 nm and 1 μm so as to give the trim face (110) interference colours, the colour of the first and second portions (111, 112) of the trim face (110) being different, wherein the decorative area (12, 13) has a different chemical composition from that of the rest of the trim face (110).

2. The trim component (10) according to claim 1, wherein the substrate (11) is made of metal, glass, sapphire, ceramic material, polymer or metal matrix composite material.

3. The trim component (10) according to claim 1, wherein the coating (14) is formed by a layer of oxide, nitride, fluoride, carbide, boride or a combination of at least two of these elements.

4. The trim component (10) according to claim 1, wherein the coating (14) is formed by a stack of layers made of oxide, nitride, fluoride, carbide and/or a combination of at least two of these elements.

5. The trim component (10) according to claim 4, wherein the coating (14) is formed by a stack of layers consisting of two layers of TiO2 with a layer of Al2O3 interposed in between.

6. The trim component (10) according to claim 1, wherein the coating (14) is configured so as to impart to the trim component (10) a colour characterised in the space L*a*b* by L* being between 28 and 60, a* being between −9 and −0.6 and b* being between 21 and 31.

7. A method for producing a decoration on a trim component (10), comprising a step of local surface treatment of the trim face (110) of a substrate (11), in which a decorative area (12, 13) is generated in the substrate, on a part of the trim face (110), so as to have a refractive index different from that of the rest of the trim face (110), the method comprising a step of depositing a coating (14) over the whole of the trim face (110) so that the trim face (110) has interference colours, wherein the local surface treatment step is carried out by electron beam evaporation, ion bombardment, or electron beam lithography so as to generate a local chemical composition change of the trim face to produce the decorative area (12, 13).

8. The method according to claim 7, wherein the local surface treatment step is carried out by laser so as to generate local annealing of the trim face in order to produce the decorative area (12, 13) by phase change, crystalline structure change, surface diffusion, oxidation, reduction or nitriding.
